(19) United States
(12) Patent Application Publication
(10) Pub. No.: US 2026/0344002 A1
(43) Pub. Date: Oct. 29, 2026

(54) HIGH-BANDWIDTH MEMORY DEVICES WITHOUT THROUGH SUBSTRATE VIAS AND ASSOCIATED SYSTEMS AND METHODS

(71) Applicant: Micron Technology, Inc., Boise, ID (US)

(72) Inventors: Sujeet Ayyapureddi, Boise, ID (US); Charles L. Ingalls, Meridian, ID (US)

(21) Appl. No.: 19/641,482

(22) Filed: Apr. 7, 2026

Related U.S. Application Data
(60) Provisional application No. 63/787,648, filed on Apr. 11, 2025.

(51) Int. Cl. H10D 80/30; H10B 80/00; H10P 58/00; H10W 40/20; H10W 46/00; H10W 72/00; H10W 72/20; H10W 72/29; H10W 90/00; H10W 90/20

(52) U.S. Cl. CPC H10D 80/30; H10B 80/00; H10P 58/00; H10W 40/233; H10W 46/301; H10W 46/503; H10W 72/07227; H10W 72/263; H10W 72/29; H10W 90/722; H10W 90/723; H10W 90/724; H10W 90/297

(57) ABSTRACT

Architectures for system-in-package (SiP) devices, high-bandwidth memory (HBM) devices that do not include through substrate vias (TSVs), and associated systems and methods, are disclosed herein. For example, an HBM device according to the present technology can include a base die as well as a plurality of memory dies integrated with an active surface of the base die. More specifically, each of the memory dies can have a lowermost surface that includes a plurality of bond sites that are each electrically coupled to a corresponding bond site on the active surface of the base die. That is, each of the memory dies can be individually coupled to the base die. Further, the base die can have a primary plane that is parallel to a horizontal axis while each of the memory dies can have a primary plane that is orthogonal to the horizontal axis (e.g., parallel to a vertical axis).

### CROSS-REFERENCE TO RELATED APPLICATIONS

The present application claims priority to U.S. Provisional Patent Application No. 63/787,648, filed Apr. 11, 2025, the disclosure of which is incorporated herein by reference in its entirety.

### TECHNICAL FIELD

The present technology is generally directed to systems and methods for constructing high-bandwidth memory devices and more specifically to architectures for constructing high-bandwidth memory devices without through substrate vias.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or addressing increases in operating temperatures with increasing density.

### BRIEF DESCRIPTION OF THE DRAWINGS

FIG. 1 is a schematic diagram illustrating an environment that incorporates a high-bandwidth memory architecture.

FIG. 2 is a partially schematic cross-sectional diagram of a system-in-package with a high-bandwidth memory device.

FIG. 3A is a partially schematic cross-sectional diagram of a high-bandwidth memory device configured in accordance with embodiments of the present technology.

FIG. 3B is a partially schematic cross-sectional diagram of a memory die for a high-bandwidth memory device configured in accordance with embodiments of the present technology.

FIG. 4 is a flow diagram of a process for constructing a high-bandwidth memory device configured in accordance with embodiments of the present technology.

FIG. 5 is a partially schematic cross-sectional diagram of a system-in-package configured in accordance with embodiments of the present technology.

FIG. 6 is a partially schematic cross-sectional diagram of a system-in-package configured in accordance with embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

Architectures for system-in-package (SiP) devices, high-bandwidth memory (HBM) devices that do not include through substrate vias (TSVs), and associated systems and methods, are disclosed herein. For example, as discussed in more detail below, an HBM device according to the present technology can include a base die as well as a plurality of memory dies (e.g., DRAM dies) that are each integrated with an active surface of the base die. More specifically, each of the memory dies can have a lowermost surface that includes a plurality of bond sites, and each of the bond sites on the memory dies can be electrically coupled to a corresponding bond site on the active surface of the base die (e.g., by a solder structure, a metal-metal bond, and/or the like). As a result, each of the memory dies can be individually coupled to the base die (e.g., such that signals to any one of the memory dies do not need to be routed through any other memory dies). Further, as also discussed in more detail below, the base die can have a first primary plane (e.g., a plane parallel to an a largest surface of the base die, such as an active and/or upper surface of the memory dies) that is parallel to a horizontal axis while each of the memory dies can have a second primary plane (e.g., a plane parallel to a largest surface of the memory dies) that is orthogonal to the horizontal axis (e.g., orthogonal to the first primary plane and parallel to a vertical axis). Said another way, the memory dies can be positioned and/or oriented vertically before they are attached to the base die.

Although the systems and methods discussed herein are discussed primarily with reference to the memory dies in an HBM device, one of skill in the art will understand that the processes of the present technology discussed herein are not so limited. Purely by way of example, the no-TSV architecture disclosed herein can be implemented in a non-volatile storage device (e.g., rotating SRAM dies to eliminate TSVs), a processing device (e.g., with various processing and/or logic dies), and/or any other suitable setting.

As used herein, the terms “vertical,” “lateral,” “upper,” “lower,” “top,” and “bottom” can refer to relative directions or positions of features in the HBM devices (and SiP devices more generally) in view of the orientation shown in the drawings. For example, “bottom” can refer to a feature positioned closer to the bottom of a page than another feature. These terms, however, should be construed broadly to include HBM devices (and SiP devices) having other orientations, such as inverted or inclined orientations where top/bottom, over/under, above/below, up/down, and left/right can be interchanged depending on the orientation.

The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

Further, unless the context indicates otherwise, structures disclosed herein can be formed using one or more semiconductor manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques.

High data reliability, high speed of memory access, lower power consumption, and reduced chip size are features that are demanded from semiconductor memory. In recent years, stacked memory devices (e.g., three-dimensional (3D) memory devices) have been introduced. Some stacked memory devices are formed by stacking memory dies vertically on a base die (e.g., a “2.5D memory device”), and interconnecting the dies using TSVs. Some stacked memory devices are formed by stacking memory dies vertically directly on a processing unit (e.g., “3D memory device”) and interconnecting the dies using TSVs. Benefits of the stacked memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5D and 3D memory devices contribute to higher memory access speed, lower power consumption, and chip size reduction. Examples of stacked memory devices include Hybrid Memory Cube (HMC) and High-Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a SiP device configuration, HBM devices may be integrated with a host device (e.g., a graphics processing unit (GPU), computer processing unit (CPU), and/or another suitable processing unit) using a base substrate (e.g., a silicon interposer, a substrate of organic material, a substrate of inorganic material and/or any other suitable material that provides interconnection between CPU/GPU and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device (and the silicon interposer integrating HBM devices and a host device) enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., CPU/GPU) and HBM devices during operation. For example, the high-bandwidth channels can be on the order of 1000s of gigabytes per second (GB/s, sometimes also referred to as gigabits (Gb)). It will be appreciated that such high-bandwidth data transfer between a CPU/GPU and the memory of HBM devices can be advantageous in various high-performance computing applications, such as video rendering, high-resolution graphics applications, artificial intelligence and/or machine learning (AI/ML) computing systems and other complex computational systems, autonomous control of vehicles, and/or various other computing applications.

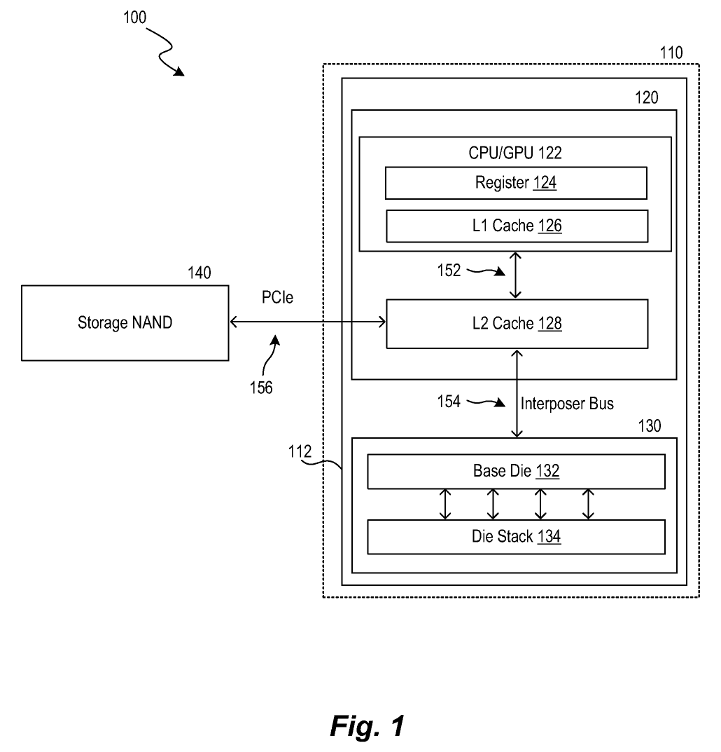

FIG. 1 is a schematic diagram illustrating an environment 100 that incorporates a high-bandwidth memory architecture. As illustrated in FIG. 1, the environment 100 includes a SiP device 110 having one or more processing devices 120 (one illustrated in FIG. 1, sometimes also referred to herein as one or more “hosts”), and one or more HBM devices 130 (one illustrated in FIG. 1), integrated with a silicon interposer 112 (or any other suitable base substrate). The environment 100 additionally includes a storage device 140 coupled to the SiP device 110. The processing device(s) 120 can include one or more processing units 122 (e.g., one or more CPUs, one or more GPUs, and/or the like), each of which may include a register 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., an interposer that is itself carried by a package substrate) adjacent to the L2 cache 128 and in communication with the L2 cache 128 via one or more signal lines (or other suitable signal route lines) therein. The L2 cache 128 may be shared by one or more of the processing devices 120 (and the processing units 122 therein). During operation of the SiP device 110, the processing units 122 can use the register 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. For example, the processing device(s) 120 (and L2 cache 128 therein) and HBM device(s) 130 can each be carried by and electrically coupled to (e.g., integrated with) the silicon interposer 112. The second communication channel 154 can be provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110 and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during the operation of the SiP device 110, the processing device(s) 120 can read data from and/or write data to the HBM device(s) 130 and/or the storage device 140, through the L2 cache 128.

Further, in the illustrated environment 100, the HBM device(s) 130 each include a base die 132 and a die stack 134 communicably coupled to the base die 132. The base die 132 can include a physical layer interface (referred to herein as a “PHY” for short) that is communicably coupled to the second communication channel 154. The PHY can receive signals from the processing device(s) 120 via the second communication channel 154 and route the signals to the die stack 134. The die stack 134 can include one or more memory dies (e.g., DRAM dies, other volatile memory dies, and/or the like) that are each communicably coupled to the PHY in the base die 132.

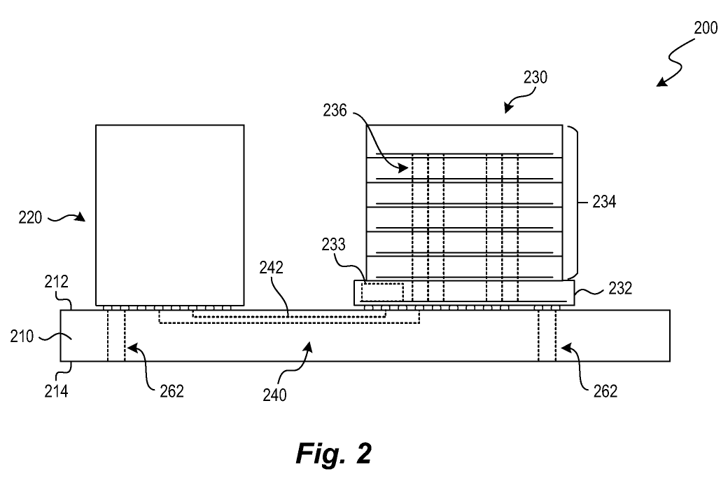

FIG. 2 is a partially schematic cross-sectional diagram of a SiP 200 that can be employed in the environment 100 discussed above with reference to FIG. 1. As illustrated in FIG. 2, the SiP 200 includes a base substrate 210 (e.g., a silicon interposer, another organic interposer, an inorganic interposer, and/or any other suitable base substrate), as well as a processing device 220 and an HBM device 230 each integrated with (e.g., carried by and electrically coupled to) an upper surface 212 of the base substrate 210.

As a result, the processing device 220 can be coupled to the HBM device 230 through a high-bandwidth bus 240 that includes a substrate bus 242. For example, the processing device 220 and the HBM device 230 can each be coupled to various route lines in the substrate bus 242 via solder structures (e.g., solder balls), metal-metal bonds, and/or any other suitable conductive bonds. The route lines of the substrate bus 242, in turn, can include one or more metallization layers formed in one or more RDL layers of the base substrate 210 and/or one or more vias interconnecting the metallization layers. As a result, the HBM device 230 and the processing device 220 can communicate data at a relatively high rate (e.g., on the order of 1000s of GB/s).

Further, as illustrated in FIG. 2, the base substrate 210 can include one or more external TSVs 262 (four illustrated in FIG. 2) that extend from the upper surface 212 of the base substrate 210 to a lower surface 214 of the base substrate 210. The external TSVs 262 can couple the processing device 220, the HBM device 230, and/or the substrate bus 242 to package interconnects (e.g., solder structures, bond pads, and/or the like) on the lower surface. In turn, the package interconnects can be coupled to an external substrate (e.g., a package substrate), thereby communicably coupling the processing device 220, the HBM device 230, and/or the substrate bus 242 to various external components.

In the environment illustrated in FIG. 2, the processing device 220 is illustrated as a single package/component. It will be understood, however, that the processing device 220 can include a variety of components, such as a processing unit (e.g., a CPU/GPU), one or more registers, an L1 cache, an L2 cache, and/or any other suitable components. In contrast, FIG. 2 illustrates a variety of specific components of the HBM device 230. For example, the HBM device 230 includes a base die 232 and\ one or more memory dies 234 (four illustrated in FIG. 2, sometimes referred to collectively as a “die stack”) integrated with the base die 232. The base die 232 (sometimes also referred to herein as an “interface die”) includes a PHY 233 and one or more metallization layers communicably coupled to the PHY 233. The HBM device 230 also includes a plurality of TSVs 236 (and/or a plurality of bonding features such as metal-metal bonded pads, solder structures, and/or the like between segments of the TSVs 236) extending through the memory dies 234 (e.g., DRAM dies). The TSVs 236 (sometimes referred to collectively as an “HBM bus”) establish a communication path between the base die 232 and each of the memory dies 234, thereby allowing the PHY 233 to route signals to (and receive signals from) each of the memory dies 234.

For example, during operation of the SiP 200, the processing device 220 can request information stored in the HBM device 230 through the substrate bus 242. The request is received by the PHY 233 of the base die 232. The PHY 233 then determines which of the memory dies 234 to request information from to satisfy the request from the processing device 220 (e.g., identifies which of the memory dies 234 stores the requested information). The PHY 233 then prompts the identified memory dies to forward the information via the HBM bus. The PHY 233 then receives the information (or an error signal) in response and forwards the information (or the error) back to the processing device 220. Operations according to the example above can share information at relatively high rates (e.g., up to an order of 1000s of GB/s), with each of the signals needing to be routed through the PHY 233. The bandwidth of the communication, however, is dependent on the quality of the connections over the TSVs 236 in each of the memory dies 234. As a result, manufacturing processes for the HBM device 230 typically require expensive manufacturing processes to produce arrays of the TSVs 236, careful alignment, expensive bonding processes to help ensure quality connections, and/or the like. Errors in the manufacturing processes, alignment, and/or bonding processes are common, resulting in significant reductions in the yield of manufacturing processes and increases in the cost per functional HBM device. Further, demands for increased memory capacity and/or increased functionality in the HBM device 230 lead to increases in the number of the memory dies 234 and/or the number of the TSVs 236. These increases are associated with further increases in the complexity and/or manufacturing challenges, as well as the associated increases in the cost per functional HBM device.

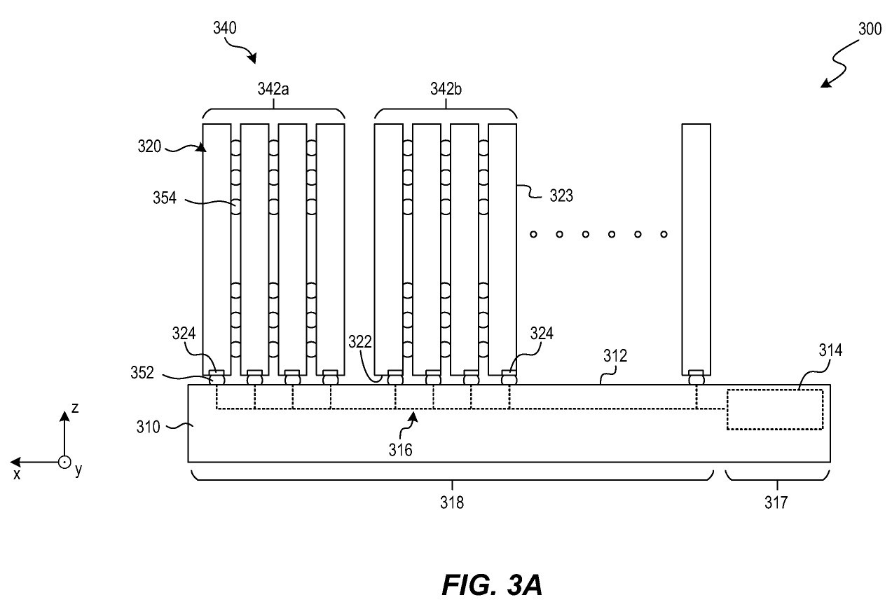

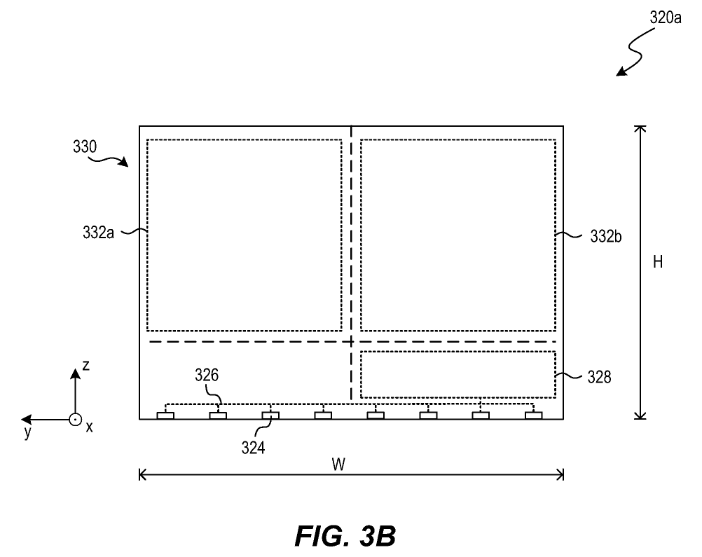

Architectures for SiP devices and HBM devices, and associated systems and methods, for addressing the challenges discussed above are disclosed herein. For example, FIG. 3A is a partially schematic cross-sectional diagram of an HBM device 300 configured in accordance with embodiments of the present technology. As illustrated in FIG. 3A, the HBM device 300 is generally similar to the HBM device 230 discussed above with reference to FIG. 2. For example, the HBM device 300 includes a base die 310 that includes an upper surface 312 (e.g., an active surface), a PHY 314, and a metallization layers 316 (shown schematically) communicably coupled to the PHY 314. Further, the HBM device 300 also includes a plurality of memory dies 320 carried by the upper surface 312 of the base die 310.

In the embodiments illustrated in FIG. 3A, however, the memory dies 320 are rotated with respect to the base die 310 such that a primary plane of the base die 310 (e.g., the x-y plane in FIG. 3A, the plane parallel to the upper surface 312 of the base die 310) is orthogonal (or at least at an angle with respect to) to a primary plane of each of the memory dies 320 (e.g., the y-z plane in FIG. 3A, a plane parallel to an active surface 323 of the memory dies 320). Said another way, the memory dies 320 are each stacked over the base die 310 in a vertical orientation. As a result, each of the memory dies 320 can be independently integrated with the base die 310. More specifically, as illustrated in FIG. 3A, each of the memory dies 320 includes a lowermost surface 322 and one or more bond sites 324 at the lowermost surface 322 (sometimes also referred to herein as a “lowermost edge”). The bond sites 324 are each coupled to one of the metallization layers 316 (e.g., bond pads, bond sites, route lines, and/or the like) at the upper surface 312 of the base die 310 by a bonding structure 352 (e.g., a metal-metal bond, a solder structure, a conductive pillar, and/or the like). Accordingly, each of the memory dies 320 can be communicably coupled to the PHY 314 in the base die 310 directly via the bond sites 324 and the metallization layers 316 (e.g., such that any given one of the memory dies 320 is communicably coupled to metallization layers 316 and/or the PHY 314 independent of any other die). That is, the architecture of the HBM device 300 illustrated in FIG. 3A can eliminate a need for TSVs to communicably couple the memory dies 320 to the PHY 314. As a result, the architecture of the HBM device 300 illustrated in FIG. 3A is expected to help alleviate the complexities and costs associated with manufacturing HBM devices discussed above with reference to FIG. 2.

Additionally, or alternatively, by eliminating the need for TSVs, the architecture of the HBM device 300 illustrated in FIG. 3A can increase the density of and/or the overall memory available on the HBM device 300. For example, the difficulties associated with TSVs discussed above can limit the number of memory dies that can be stacked on and reliably coupled to the base die. As a result, there is an upper limit to the number of memory dies that can be reliably integrated with the base die in a stacked-die, TSV-reliant architecture. In contrast, the TSV-free architecture of the HBM device 300 illustrated in FIG. 3A can allow any suitable number of the memory dies 320 to be reliably integrated with the base die 310, such that the HBM device 300 is only limited by the available footprint. Further, the omission of the TSVs (and their required footprint) can provide additional room for memory circuits on each of the memory dies 320, allowing each of the memory dies 320 to provide additional memory space. As a result, the omission of the TSVs can help increase a density of memory available within a given footprint. Additionally, or alternatively, the omission of the TSVs can allow the memory dies 320 to be thinner (e.g., between an active surface and an inactive surface) than a memory die that includes the TSVs (and associated routing structures). As a result, the HBM device 300 can fit more of the memory dies 320 into a given footprint, thereby increasing the density of the available memory.

In some embodiments, the independent integration of the memory dies 320 allows the HBM device 300 to modify an allocation of memory channels. For example, FIG. 3B is a partially schematic cross-sectional diagram of an individual memory die 320a configured in accordance with embodiments of the present technology. As illustrated in the cross-section of FIG. 3B (taken along the y-z plane), the individual memory die 320a can include route lines 326 extending between the bond sites 324 and a routing circuit 328 (e.g., a die-logic circuit), as well as a memory circuit 330. As discussed above, the memory dies 320 (FIG. 3A) are each coupled to the PHY 314 through the metallization layers 316. As a result, each of the memory dies 320 (FIG. 3A) can be accessible with a generally comparable latency. The comparable latency, in turn, can allow the memory circuit 330 to provide an entire channel of memory while maintaining parity in the latency between channels. That is, rather than dividing channels of memory across multiple stacked memory dies in the HBM device (e.g., as typical for an HBM device of the type discussed above with reference to FIGS. 1 and 2), the TSV-free architecture of the HBM device 300 (FIG. 3A) allows each channel to be contained entirely within memory circuit 330 of the individual memory die 320a.

In some embodiments, one or more of the channels has a pseudo-channel architecture. For example, as further illustrated in FIG. 3B, the memory circuit 330 of the individual memory die 320a can be divided into a first subchannel 332a (e.g., a first pseudo channel) and a second subchannel 332b (e.g., a second pseudo channel). In such embodiments, the first and second subchannels 332a, 332b can operate semi-independently (e.g., as channels that share the same address and command bus, but decode and execute commands individually). In some embodiments, first and second subchannels 332a, 332b can operate as redundant channels to store a back-up of information.

As further illustrated in FIG. 3B, the individual memory die 320a (and, by extension, one or more of the memory dies 320 in FIG. 3A), has a width W and a height H. The width W and height H can be selected to maximize the memory space available on the individual memory die 320a. For example, the width W and height H can match a maximum width and/or a maximum height (minus the thickness of the base die 310 (FIG. 3A) and any bonding features) available for a footprint of the HBM device 300. Additionally, or alternatively, the width W and height H can be selected to match the available memory to a desired amount of memory for the HBM device 300 (FIG. 3A). Additionally, or alternatively, the width W and height H can be selected to, match the dimensions of the HBM device 300 (FIG. 3A) to another component (e.g., the processing device 220 of FIG. 2). In any of the embodiments discussed above, referring to FIGS. 3A and 3B together, the height H is larger than a depth of the individual memory die 320a (or any of the memory dies 320), such that a surface area of the active surface 323 is larger than a surface area of the lowermost surface 322. That is, in the vertical orientation, the sidewall of the memory dies 320 can have a larger surface area than the lowermost edges of the memory dies 320.

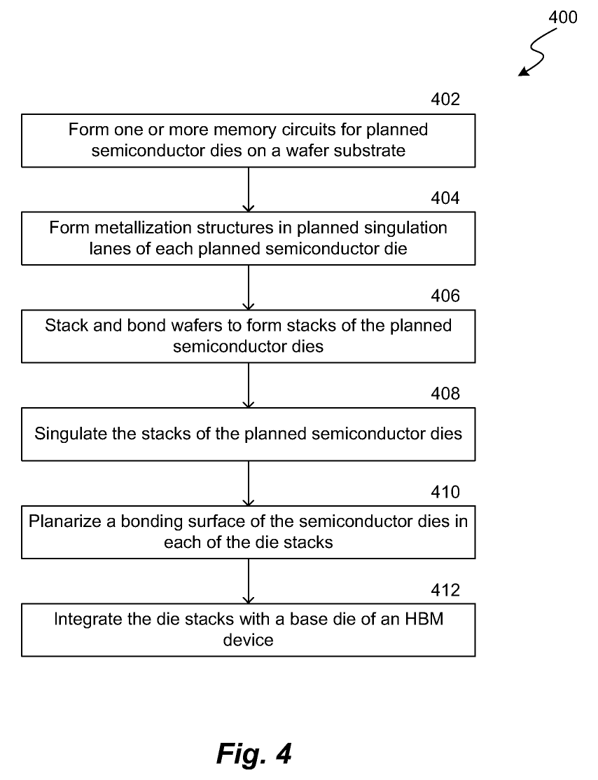

Returning to the description of FIG. 3A, the memory dies 320 can be physically coupled in one or more packages 340 before being integrated with the base die 310. For example, as discussed in more detail below with reference to FIG. 4, the memory dies 320 can be produced in a wafer-level process. Wafers of the memory dies can then be stacked and physically coupled (e.g., mechanically coupled but not communicatively coupled) by one or more bonding structures 354 (e.g., metal-metal bonds, solder structures, and/or the like). The wafers can then be singulated to isolate individual stacks of the memory dies 320 in the packages 340, which are then integrated with the base die 310 of the HBM device 300. By grouping the memory dies 320 into the packages 340, the manufacturing process can help streamline the packaging process for the HBM device 300 and/or reduce the chance that individual memory dies are damaged during packaging.

As discussed in more detail below with reference to FIG. 4, the memory dies 320 can be produced in a wafer-level process. In such embodiments, the bond sites 324 (sometimes also referred to herein as “bonding structures,” “metal structures,” “metallization layers,” and/or the like) can be formed by forming metal structures and/or metal layers at planned singulation lines in the wafer. The singulation process (e.g., a stealth dicing process, mechanical dicing process, chemical etching process, and/or the like) can then expose the bond sites 324. In various embodiments, the bond sites 324 can be formed during front-end-of-line processes (FEOL) and/or back-end-of-line processes (BEOL), each of which can result in a slightly different location of the bond sites 324 on the corresponding memory dies 320. For example, as further illustrated in FIG. 3A, the bond sites 324 for the memory dies 320 in a first package 342a are positioned generally centrally on the lowermost surface 322. In contrast, the bond sites 324 for the memory dies 320 in a second package 342b are positioned on the lowermost surface 322 adjacent to the active surface 323 of the memory dies 320 (sometimes also referred to herein as a “sidewall” and/or the like based the vertical orientation of the memory dies 320).

In some embodiments, the additional memory space and independent connection allows one or more of the memory dies 320 to be designated as a backup memory die. Purely by way of example, the memory dies 320 in the second package 342b can be designated as backups for the memory dies 320 in the first package 342a. In this example, the backup memory die can be utilized when one or more other memory dies fail due to a failure in the connection to the failing memory die, such as a break in the bonding structure 352 and/or failure within the memory die itself. In this example, because the backup memory die is coupled to the PHY 314 independent from the failing memory die, the break in the bonding structure 352 for the failing memory die has no impact on the connection to the backup memory die. As a result, the independent connection can help increase a lifetime and/or a reliability of the HBM device 300.

In some embodiments, the components of the HBM device 300 are positioned heat-consciously. For example, the PHY 314 in the base die 310 is typically the primary source of heat for the HBM device. Unmitigated, the heat can raise the operating temperature of the memory dies 320, eventually requiring increased refresh rates, increased power consumption, and/or thermal throttling to reduce signal activity. To help reduce the impact of heat, as further illustrated in FIG. 3A, each of the memory dies 320 can be spaced apart from the PHY 314 (e.g., not aligned with the PHY 314 along the z-axis and/or not vertically aligned with). For example, as illustrated in FIG. 3A, the PHY 314 can be positioned in a first region 317 of the base die 310 while the memory dies 320 are each integrated with the upper surface 312 of the base die 310 over a second region 318 that is laterally spaced apart from the first region 317. The lateral spacing can help provide a physical buffer between the memory dies 320 and the PHY 314, thereby reducing the amount of health that builds up within the memory dies 320 during operation. Further, because the TSV-free construction can allow the HBM device 300 to include additional memory within a given horizontal footprint (e.g., via increased density), the TSV-free construction of the HBM device 300 can help increase the lateral space between the PHY 314 and the memory dies 320. As a result, the TSV-free construction can help reduce an operating temperature of the memory dies 320, thereby helping mitigate the deleterious effects of heat discussed above.

Additionally, or alternatively, the memory dies 320, in some embodiments, include thermal-management features. For example, each of the memory dies can include a sidewall (e.g., a surface opposite the active surface 323) that includes one or more metallization lines that extend along the z-axis. As a result, the metallization layers can provide thermal pathways extending away from the upper surface 312 of the base die 310 to help route heat through the memory dies 320 more quickly.

FIG. 4 is a flow diagram of a process 400 for constructing a high-bandwidth memory device configured in accordance with embodiments of the present technology. The process 400 can be implemented by a single manufacturing apparatus and/or split between multiple manufacturing apparatuses to construct HBM devices with an architecture of the type discussed above with reference to FIGS. 3A and 3B (e.g., with vertically-oriented memory dies and/or without TSVs).

The process 400 begins at block 402 by forming one or more memory circuits, in and/or on a wafer substrate, for planned semiconductor dies on the wafer substrate. The formation can include various FEOL processes and/or one or more BEOL processes to interconnect memory circuits. In some embodiments, the process 400 at block 402 includes forming one or more related circuits, such as a logic and/or routing circuit for each of the planned semiconductor dies.

At block 404, the process 400 includes forming metallization structures, in and/or on the wafer substrate, that at least partially overlap with planned singulation lanes for each of the planned semiconductor dies. The formation can include various FEOL processes and/or one or more BEOL processes to deposit one or more layers of metal, thereby creating bond sites at the planned singulation lanes and electrically coupling each of the bond sites to the memory circuits formed at block 402. In some embodiments, the metallization structures are formed at an uppermost surface of the wafer. In some embodiments, the metallization structures are formed at an intermediate depth within the wafer substrate.

At block 406, the process 400 includes stacking two or more wafers and bonding the stacked wafers to form stacks of the planned semiconductor dies. For example, the process 400 at block 406 can include aligning planned semiconductor dies from a first wafer substrate with planned semiconductor dies from a second wafer substrate, then stacking the first wafer substrate on top of the second wafer substrate. The process 400 can then bond the first and second wafer substrates together via a reflow process (e.g., to reflow one or more solder structures between the first and second wafer substrates), a direct bonding process (e.g., to form one or more metal-metal bonds and/or substrate-substrate bonds via heating and/or compression), and/or the like. In some embodiments, the bonds are formed between non-functional bonding features on the first and second wafers (e.g., non-functional and/or electrically isolated bond sites). As a result, the bonds form a physical connection between the planned semiconductor dies from the first wafer substrate and the planned semiconductor dies from the second wafer substrate but do not electrically couple the planned dies. In various embodiments, the process 400 at block 406 can create die stacks of any suitable height (e.g., of two dies, three dies, four dies, eight dies, ten dies, and/or any other suitable number). In various embodiments with three or more dies per stack, the process can bond each of the wafers together in a single process, can bond subsets of the wafers together iteratively (e.g., bonding three wafers at a time), and/or can bond a single wafer to the stack iteratively until the stack is complete.

At block 408, the process 400 includes singulating the stacks of planned semiconductor dies along the planned singulation lines. The singulation can include a steal-dicing process, a mechanical dicing process (e.g., using a diving saw), a laser dicing process, one or more chemical etching processes, and/or any other suitable process. Because the singulation process traces the planned singulation lines, the singulation process at block 408 exposes sidewalls of the metallization structures formed at block 404 along the actual singulation lines. The sidewalls, in turn, provide a surface to electrically access the metallization structures (e.g., the bond sites) and therefore the memory circuits via the sidewalls of resulting die stacks and metal route lines in each of the semiconductor dies.

At block 410, the process 400 includes planarizing the sidewalls of each of the die stacks (sometimes referred to herein as a “bonding surface” of the die stacks). In various embodiments, the planarization process can include a mechanical grinding process, a chemical etching process, and/or any other suitable process. The planarization can help clean up and/or smooth the exposed portions of the metallization structures (e.g., the exposed bond sites), thereby providing a planar bonding surface across the die stack. As a result, the bond sites for each of the semiconductor dies in the die stack is accessible at the planar bonding surface, allowing the bonding surface of the die stack to be integrated with another substrate.

At block 412, the process 400 includes integrating one or more of the resulting die stacks with a base die of an HBM device. Integrating the die stacks can include rotating the die stacks such that the bonding surface becomes the lowermost surface of the die stacks, aligning the bond sites at the bonding surface of the die stack with corresponding bond sites on the base die, stacking the die stack over the base die, and electrically coupling the bond sites on the bonding surface to the corresponding bond sites on the base die. Electrically coupling the bond sites on the bonding surface to the corresponding bond sites on the base die can include forming one or more solder bonds (e.g., reflowing solder structures), one or more metal-metal bonds (e.g., via an annealing process with pressure and/or heat), and/or the like. Once block 412 is complete, each of the semiconductor dies in the die stacks integrated with the base die can be individually coupled to the base die. Said another way, once block 412 is complete, each of the semiconductor dies is directly electrically coupled to the base die, without a need for TSVs in any of the die stacks.

Although blocks 402–412 are illustrated and discussed with reference to FIG. 4 in a particular order, one of skill in the art will understand that the technology disclosed herein is not so limited. Purely by way of example, the semiconductor dies from individual wafers can be singulated before forming the die stacks (e.g., by executing block 408 before block 406). In a related example, one or more of the sub-processes discussed above can be combined into a single stage of the process 400. In a specific, non-limiting example, the metallization structures can be formed generally simultaneously with the memory (and other) circuits in the semiconductor die (e.g., by combining block 402 and 404), thereby allowing all of the conductive features to be formed in the wafer substrate generally simultaneously.

Additionally, or alternatively, it will be understood that the process 400 can include various additional steps and/or sub-processes and/or can omit various steps and/or sub-processes. For example, the process 400 can include forming solder structures on each of the bond sites exposed at the bonding surfaces after planarizing the bonding surface at block 410 (and before integrating the die stacks with the base die at block 412). In another example, the process 400 can include a backgrinding process on the wafer substrate before stacking and bonding the wafers at block 406. In this example, the backgrinding process can remove excess material from a backside of the wafer substrate (e.g., an inactive surface), thereby creating thinner semiconductor dies for the die stacks and/or increasing a density of the memory in the resulting die stacks. In yet another example, the process 400 can omit block 406 altogether and instead singulate dies from a single wafer, planarize individual resulting dies, and integrate the dies with the base die individually. The individual processing can help reduce a chance of damage to the semiconductor dies from singulating the dies in stacked wafers (e.g., due to crack migration, higher stress forces, and/or the like). In yet another example, the process 400 can include various other packaging processes after integrating the die stacks with the base die. In various specific examples, the process 400 can include depositing a mold compound over the base die and around the die stacks, attaching a thermal lid to an upper surface of the die stacks, integrating the base die with another substrate (e.g., a silicon interposer, another organic interposer, an inorganic interposer, and/or any other suitable base substrate of a SiP device), and/or the like.

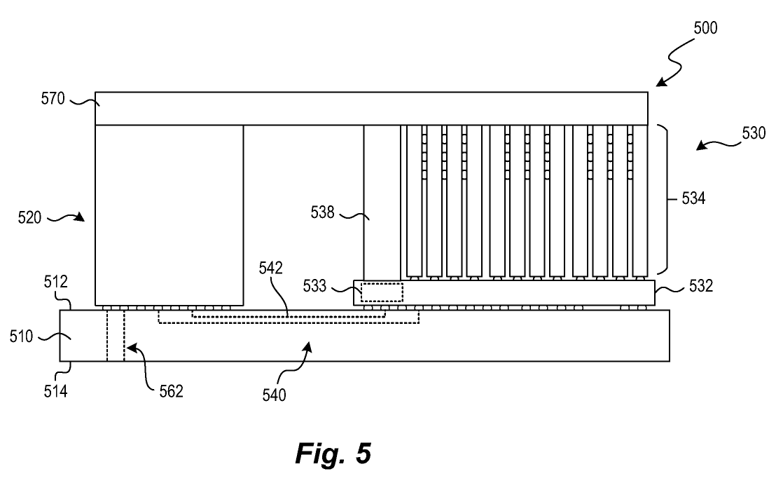

FIG. 5 is a partially schematic cross-sectional diagram of a SiP 500 configured in accordance with embodiments of the present technology. In the illustrated embodiments, the SiP 500 is generally similar to the SiP 200 discussed above with reference to FIG. 2. For example, the SiP 500 of FIG. 5 includes a base substrate 510, as well as a processing device 520 and an HBM device 530 integrated with an upper surface 512 of the base substrate. Further, the processing device 520 is coupled to the HBM device 530 through a high-bandwidth bus 540 that includes a substrate bus 542. As a result, the HBM device 530 and the processing device 520 can communicate data at a relatively high rate (e.g., on the order of 1000s of GB/s). Still further, as illustrated in FIG. 5, the base substrate 510 can include one or more external TSVs 562 (two illustrated in FIG. 2) that extend from the upper surface 512 of the base substrate 510 to a lower surface 514 of the base substrate 510. The external TSVs 562 can couple the processing device 520, the HBM device 530, and/or the substrate bus 542 to package interconnects on the lower surface. In turn, the package interconnects can be coupled to an external substrate (e.g., a package substrate), thereby communicably coupling the processing device 520, the HBM device 530, and/or the substrate bus 542 to various external components.

Similar to the discussion above, the processing device 520 is illustrated in FIG. 5 as a single package/component. It will be understood, however, that the processing device 520 can include a variety of components, such as a processing unit (e.g., a CPU/GPU), one or more registers, an L1 cache, an L2 cache, and/or any other suitable components. Further, in the illustrated embodiments, the HBM device 530 is generally similar to the HBM device 300 discussed above with reference to FIGS. 3A and 3B. For example, the HBM device 530 includes a base die 532 and a plurality of memory dies 534 oriented vertically and individually integrated with the base die 532. As a result, each of the memory dies (e.g., DRAM dies) can be electrically coupled to a PHY 533 in the base die 532 independent of each other and without a need for TSVs. As discussed above, the TSV-free architecture can help increase a density of memory available in the HBM device 530, an overall memory available in the HBM device 530, decrease manufacturing costs for the HBM device 530 (and the SiP more generally), and/or a reliability of the connections between the memory dies 534 and the base die 532.

In the illustrated embodiments, the HBM device 530 also includes a thermal transfer structure 538 carried by the base die 532 adjacent to the memory dies 534. The thermal transfer structure 538 can be partially (or fully) vertically aligned with the PHY 533, thereby allowing the thermal transfer structure 538 to provide a direct thermal path away from the PHY 533 for heat generated therein. Still further, as illustrated in FIG. 5, the SiP 500 can include a thermal lid 570 that is carried by the processing device 520 and the HBM device 530. More specifically, an uppermost surface of the memory dies 534 and/or the thermal transfer structure can be coplanar with a topmost surface of the processing device 520, and the thermal lid 570 can be carried thereon. As a result, The thermal lid 570 can receive and dissipate heat from the processing device 520 (e.g., from a CPU/GPU) and/or the HBM device 530 (e.g., from the PHY 533, via the thermal transfer structure 538 and/or the memory dies 534). In some embodiments, the combination of the thermal transfer structure 538 and the thermal lid 570 helps reduce an operating temperature of the memory dies 534 by providing a path for heat to be dissipated from the PHY 533 that is fully peripheral to the memory dies 534.

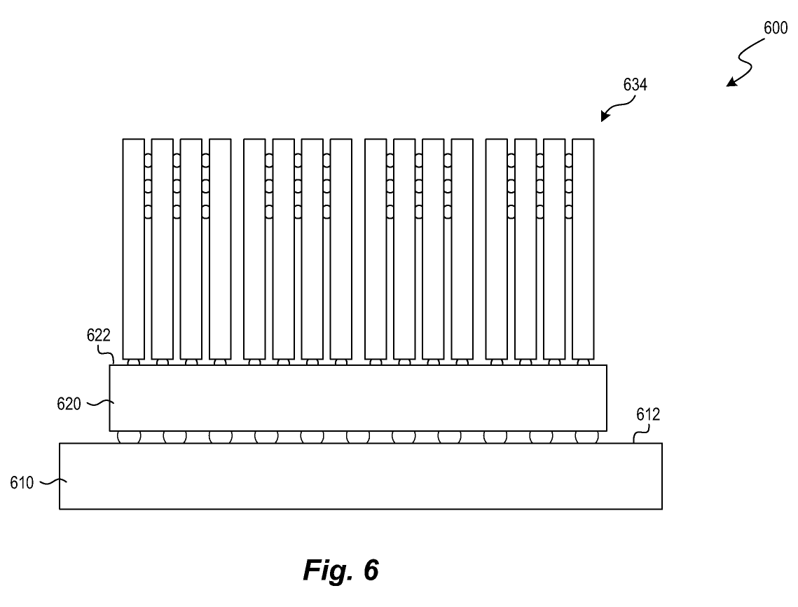

FIG. 6 is a partially schematic cross-sectional diagram of a SiP 600 configured in accordance with further embodiments of the present technology. In the illustrated embodiments, the SiP 600 is generally similar to the SiP 500 discussed above with reference to FIG. 5, modified to have a “3D architecture” (e.g., as compared to the 2.5D architecture of FIG. 5). For example, as illustrated in FIG. 6, the SiP 600 includes a base substrate 610, as well as a processing device 620 and a plurality of memory dies 634 carried by an upper surface 612 of the base substrate 610. In the illustrated embodiment, however, the processing device 620 is integrated with the upper surface 612 of the base substrate 610 and the plurality of memory dies 634 are integrated directly with an upper surface 622 of the processing device 620 (e.g., thereby omitting the substrate bus discussed above). The direct integration of the memory dies 634 with the upper surface 622 of the processing device 620 can help provide a high-bandwidth communication path between the memory dies 634 and the processing device 620 while reducing an overall distance of the communication path. Additionally, or alternatively, the direct integration can help reduce a longitudinal footprint required for the SiP.

As further illustrated in FIG. 6, the memory dies 634 are each individually integrated with the upper surface 622 and positioned in a vertical orientation. As a result, similar to the discussion above, the memory dies 634 can each be electrically coupled to the processing device 620 without TSVs extending through any of the memory dies 634. The omission of the TSVs, as discussed above, can help increase a density of the memory available in the SiP 600, increase an overall amount of memory available in the SiP 600, increase a reliability of the connections, and/or reduce manufacturing costs for the SiP 600.

### Conclusion

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally, “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall

within the scope of the technology. Accordingly, the disclosure and associated technology can encompass other embodiments not expressly shown or described herein.

We claim:

1. A high-bandwidth memory (HBM) device, comprising:
a base die having a first primary plane that is parallel to a horizontal axis; and
a plurality of memory dies integrated with an active surface of the base die, wherein:
each of the plurality of memory dies comprises a lowermost surface having a plurality of bond sites, wherein each of the plurality of bond sites is individually electrically coupled to a corresponding bond site on the active surface of the base die; and
each of the plurality of memory dies has a second primary plane that is orthogonal to the horizontal axis.

2. The HBM device of claim 1 wherein each of the plurality of memory dies comprises a first set of memory circuits corresponding to a first pseudo-channel of memory and a second set of memory circuits corresponding to a second pseudo-channel of memory.

3. The HBM device of claim 1 wherein each of the plurality of bond sites in each of the plurality of memory dies is individually electrically coupled to the corresponding bond site on the active surface of the base die via a solder structure.

4. The HBM device of claim 1 wherein a first memory die from the plurality of memory dies is physically coupled to a second memory die from the plurality of memory via a bonding structure between the first memory die and the second memory die, and wherein the bonding structure between the first memory die and the second memory die is not electrically functional.

5. The HBM device of claim 1 wherein the base die comprises a signal routing circuit formed in a first region of the base die, and wherein the plurality of memory dies integrated with the active surface over a second region of the base die spaced apart from the first region.

6. The HBM device of claim 5, further comprising a thermally conductive structure thermally coupled to the active surface over the first region.

7. The HBM device of claim 1 wherein, for each of the plurality of memory dies, each of the plurality of bond sites comprises a metal structure exposed at the lowermost surface of the memory die.

8. The HBM device of claim 1 wherein:
each of the plurality of memory dies comprises a metallization layer extending parallel to the second primary plane; and
for each of the plurality of memory dies, each of the plurality of bond sites comprises a sidewall of a conductive pad in the metallization layer exposed at the lowermost surface of the memory device.

9. A system-in-package device, comprising:
an interposer;
a processing unit integrated with the interposer; and
a high-bandwidth memory (HBM) device integrated with the interposer and communicatively coupled to the processing unit via an interposer bus, the HBM device comprising:
a base die; and
a plurality of memory dies carried by the base die, wherein each of the plurality of memory dies comprises a lowermost edge independently integrated with a corresponding communication channel on the base die.

10. The system-in-package device of claim 9 wherein:
for each of the plurality of memory dies, the lowermost edge has a first surface area; and
each of the plurality of memory dies further comprises a sidewall having a second surface area greater than the first surface area.

11. The system-in-package device of claim 9 wherein the plurality of memory dies comprises:
a first subset of dies mechanically coupled together by one or more bonding structures between adjacent dies in the first subset of dies; and
a second subset of dies spaced apart from the first subset of dies and mechanically coupled together by one or more bonding structures between adjacent dies in the second subset of dies.

12. The system-in-package device of claim 9 wherein each memory die in the plurality of memory dies is independently communicably coupled to a physical layer (PHY) in the base die.

13. The system-in-package device of claim 9 wherein each of the plurality of memory dies further comprises an uppermost surface coplanar with an upper surface of the processing unit.

14. The system-in-package device of claim 9 wherein the plurality of memory dies do not include electrically functional through substrate vias.

15. The system-in-package device of claim 9 wherein each memory die in the plurality of memory dies further comprises a sidewall and one or more thermal pathways formed on the sidewall.

16. The system-in-package device of claim 9 wherein the base die comprises a physical layer (PHY) formed in a first region of the base die, and wherein the plurality of memory dies are carried by the base die over a second region of the base die adjacent to the first region.

17. A method for producing a high-bandwidth memory (HBM) device, the method comprising:
for each of a plurality of memory dies on a first wafer, forming metallization structures that at least partially overlap with planned first singulation lanes on the first wafer;
stacking a second wafer over the first wafer, wherein stacking the second wafer over the first wafer comprises aligning planned second singulation lanes on the second wafer with the planned first singulation lanes on the first wafer;
singulating individual die stacks from the first and second wafers, each of the individual die stacks comprising a first memory die from the first wafer and a second memory die from the second wafer;
for each of the individual die stacks, planarizing a first sidewall of the first memory die and a second sidewall of the second memory die; and
for one or more of the individual die stacks, integrating the first sidewall of the first memory die and the second sidewall of the second memory die with an upper surface of a base die of the HBM device.

18. The method of claim 17 wherein the first sidewall of the first memory die comprises a plurality of first bond sites, wherein the second sidewall of the second memory die comprises a plurality of second bond sites, and wherein integrating the first sidewall of the first memory die and the second sidewall of the second memory die with the upper surface of a base die comprises:
electrically coupling the plurality of first bond sites to respective bond sites on the upper surface of the base die; and
electrically coupling the plurality of second bond sites to respective bond sites on the upper surface of the base die.

19. The method of claim 17, further comprising stacking a third wafer over the second wafer before singulating the individual die stacks of memory dies, wherein stacking the third wafer over the second wafer comprises aligning planned third singulation lanes on the third wafer with the planned second singulation lanes on the second wafer.

20. The method of claim 17 wherein stacking the second wafer over the first wafer further comprises forming one or more mechanical bonds between corresponding dies in the first wafer and the second wafer.
